(19) United States
(12) Patent Application Publication
(10) Pub. No.: US 2024/0038914 A1
(43) Pub. Date: Feb. 1, 2024

(54) LIGHT EMITTING CURVED LAMINATED PANEL AND COMBINED LIGHT EMITTING SOLAR PANEL AND METHOD OF MANUFACTURE THEREOF

(71) Applicant: APTERA MOTORS CORP., San Diego, CA (US)

(72) Inventors: Anuj M. THAKKAR, San Diego, CA (US); Jesse H. WOOD, San Diego, CA (US)

(73) Assignee: APTERA MOTORS CORP., San Diego, CA (US)

(21) Appl. No.: 18/357,128

(22) Filed: Jul. 23, 2023

Related U.S. Application Data
(60) Provisional application No. 63/393,941, filed on Jul. 31, 2022.

(51) Int. Cl. H01L 31/048; H01L 31/12

(52) U.S. Cl. CPC H01L 31/0488; H01L 31/125

(57) ABSTRACT

The invention relates to an apparatus, system and method for a doubly curved panel with a light emitting element, such as for a body panel of an automobile. Also described is a doubly curved solar panel with doubly curved solar cells and a light emitting element. The light emitting element may be of the LED or electroluminescent type and be embedded in the solar panel while remaining electrically decoupled from the solar array. The solar panel comprises doubly-curved substrate and superstrate preforms and at least one rigid layer. The preforms may comprise one or more strengthened glass and/or polymer layers. Polymer preforms may be formed by flat lamination followed by thermoforming. A core comprising lower and upper encapsulant layers sandwiching the light emitting element and solar cell array is disposed between substrate and superstrate preforms forming a lamination stack which is then subjected to a lamination process.

### CROSS REFERENCE TO RELATED APPLICATIONS

This application claims priority to U.S. Provisional Patent Application No. 63/393,941, filed Jul. 31, 2022, entitled, “LIGHT EMITTING CURVED LAMINATED PANEL AND COMBINED LIGHT EMITTING SOLAR PANEL AND METHOD OF MANUFACTURE THEREOF”, the disclosure of which is incorporated by reference herein in its entirety.

### FIELD OF THE INVENTION

The present disclosure relates to an apparatus, system, and method for integrating a light emitting element in a laminated panel with one or more axes of curvature and/or a laminated panel with a light emitting element and one or more solar cells.

### BACKGROUND OF THE INVENTION

Some conventional flat laminated panels have integrated light emitting elements. However, laminated panels having a light emitting element formed with one or two axes of curvature, such as those intended for use in a vehicle, are not widely available due to a variety of reasons. For example, in contrast to planar laminated panels, during lamination a non-planar panel may be subjected to a more non-uniform distribution of temperatures and stresses that can damage the light emitting element, reduce lamination uniformity, or cause delamination. Consequently, there is a need for a laminated panel with complex geometry incorporating a light emitting element without damage to that element.

Forming a laminated solar panel having a light emitting assembly (LEA) and a solar cell, or solar array, is also challenging due to the need for separate circuits for the light emitting and light receiving elements, e.g. solar cells, and the limited space available for wires, traces, busbars and other interconnects. Care must be taken to avoid shorting the separate circuits or the interconnects in the laminated solar panel.

Consequently, there is a need for a laminated panel with two-axes of curvature integrated with a LEA and one or more solar cells also having two axes of curvature. Such panels are useful when assembled to a vehicle to provide an external indicator, or for a decorative appearance. The present invention provides such a laminated panel integrated with a LEA.

### SUMMARY OF THE INVENTION

It is an object of the present invention to provide an apparatus, system, and method for encapsulating a light emitting element in a laminated panel with one or two-axes of curvature wherein the light emitting element is also singly or doubly curved.

It is an object of the present invention to provide an apparatus, system, and method for integrating a light emitting element having a stiffness greater than that of the encapsulants and laminates with which it is integrated, wherein the laminated panel is singly or doubly curved and the light emitting element remains flat.

It is an object of the present invention to provide an apparatus, system and method for encapsulating a light emitting element and solar cells to create a laminated, solar-enabled body panel for a vehicle with one or two-axes of curvature wherein the solar cells are also curved in one or two dimensions.

It is an object of the present invention to provide a solar panel with a light emitting element including a light emitting diode (LED) panel and/or an electroluminescent (EL) panel protected from environmental conditions with improved aesthetics and ease of assembly with a supporting structure.

It is an object of the present invention to provide a system and method for producing a solar panel with a light emitting element with the qualities of wear and impact resistance, durability, and long-term performance.

It is an object of the present invention to provide a lamination process for integrating a light emitting assembly with a solar panel with the above properties at a low cost and in high volume.

Other desirable features and characteristics will become apparent from the subsequent detailed description, the drawings, and the appended claims, when considered in view of this summary.

### BRIEF DESCRIPTION OF THE DRAWINGS

Non-limiting and non-exhaustive embodiments of the present invention are described with reference to the following drawings. In the drawings, like reference numerals refer to like parts throughout the various figures unless otherwise specified.

For a better understanding of the present disclosure, reference will be made to the following Detailed Description, which is to be read in association with the accompanying drawings, which are incorporated in and constitute a part of this specification, show certain aspects of the subject matter disclosed herein and, together with the description, help explain some of the principles associated with the disclosed implementations, wherein:

FIG. 1A illustrates a perspective view of a light-emitting assembly integrated with a laminated panel, according to an embodiment of the present invention;

FIG. 1B, taken along section A-A of FIG. 1A, illustrates a section view of a light-emitting assembly integrated with a laminated panel, according to an embodiment of the present invention;

FIG. 2A illustrates an exploded view of a lamination stack for fabricating a laminated panel with a light emitting assembly with two axes of curvature, according to an embodiment of the present invention;

FIG. 2B illustrates an exploded view of a partially aligned and assembled lamination stack for fabricating a laminated panel with a light emitting assembly with two axes of curvature, according to an embodiment of the present invention;

FIG. 2C illustrates an exploded view of a fully aligned and assembled lamination stack for fabricating a laminated panel with a light emitting assembly with two axes of curvature, according to an embodiment of the present invention;

FIG. 3A illustrates a perspective view of doubly curved solar panel with doubly curved solar cells and light emitting assembly, according to an embodiment of the present invention;

FIG. 3B illustrates an enlarged cross-sectional view of section 3B of a doubly curved solar panel with doubly curved solar cells and light emitting assembly, according to an embodiment of the present invention;

FIG. 4 illustrates a perspective view of a doubly curved solar cell array, according to an embodiment of the present invention;

FIG. 5A illustrates an enlarged perspective view of an EL light-emitting assembly integrated with a laminated solar cell array according to section B of FIG. 3A, according to an embodiment of the present invention;

FIG. 5B illustrates a cross-sectional view of an EL light-emitting assembly integrated with a laminated solar cell array according to section C-C of FIG. 5A, according to an embodiment of the present invention;

FIG. 6A illustrates an enlarged perspective view of an LED light-emitting assembly with an omnidirectional diffuser integrated with a laminated solar cell array, according to section B of FIG. 3A, according to an embodiment of the present invention;

FIG. 6B illustrates an enlarged perspective view of an LED light-emitting assembly with an omnidirectional diffuser in the shape of a logo integrated with a laminated solar cell array according to section B of FIG. 3A, according to an embodiment of the present invention;

FIG. 6C illustrates a cross-sectional view of an LED light-emitting assembly with an omnidirectional diffuser integrated with a laminated solar cell array according to section D-D of FIG. 6A, according to an embodiment of the present invention;

FIG. 6D illustrates an exploded perspective view of an LED light-emitting assembly with an omnidirectional diffuser in the shape of a logo for integrating with a laminated solar panel, according to an embodiment of the present invention;

FIG. 7A illustrates an enlarged perspective view of an LED light-emitting assembly with a unidirectional diffuser integrated with a laminated solar cell array according to section B of FIG. 3A, according to an embodiment of the present invention;

FIG. 7B illustrates a cross-sectional view of an LED light-emitting assembly with a unidirectional diffuser integrated with a laminated solar cell array according to section E-E of FIG. 7A, according to an embodiment of the present invention;

FIG. 8A illustrates an exploded view of a lamination stack for integrating a light emitting assembly with a laminated solar panel with two axes of curvature, according to an embodiment of the present invention;

FIG. 8B illustrates an exploded view of a partially aligned and assembled lamination stack for integrating a light emitting assembly with a laminated solar panel with two axes of curvature, according to an embodiment of the present invention; and

FIG. 8C illustrates an exploded view of a fully aligned and assembled lamination stack for integrating a light emitting assembly with a laminated solar panel with two axes of curvature, according to an embodiment of the present disclosure.

### DETAILED DESCRIPTION

Non-limiting embodiments of the present invention will be described below with reference to the accompanying drawings, wherein like reference numerals represent like elements throughout. While the invention has been described in detail with respect to the preferred embodiments thereof, it will be appreciated that upon reading and understanding of the foregoing, certain variations to the preferred embodiments will become apparent, which variations are nonetheless within the spirit and scope of the invention.

The terms “a” or “an”, as used herein, are defined as one or as more than one. The term “plurality”, as used herein, is defined as two or as more than two. The term “another”, as used herein, is defined as at least a second or more. The terms “including” and/or “having”, as used herein, are defined as comprising (i.e., open language). The term “coupled”, as used herein, is defined as connected, although not necessarily directly, and not necessarily mechanically.

Reference throughout this document to “some embodiments”, “one embodiment”, “certain embodiments”, and “an embodiment” or similar terms means that a particular feature, structure, or characteristic described in connection with the embodiment is included in at least one embodiment of the present invention. Thus, the appearances of such phrases or in various places throughout this specification are not necessarily all referring to the same embodiment. Furthermore, the particular features, structures, or characteristics may be combined in any suitable manner in one or more embodiments without limitation.

The term “or” as used herein is to be interpreted as an inclusive or meaning any one or any combination. Therefore, “A, B or C” means any of the following: “A; B; C; A and B; A and C; B and C; A, B and C”. An exception to this definition will occur only when a combination of elements, functions, steps or acts are in some way inherently mutually exclusive.

The drawings featured in the figures are provided for the purposes of illustrating some embodiments of the present invention, and are not to be considered as limitation thereto. Term “means” preceding a present participle of an operation indicates a desired function for which there is one or more embodiments, i.e., one or more methods, devices, or apparatuses for achieving the desired function and that one skilled in the art could select from these or their equivalent in view of the disclosure herein and use of the term “means” is not intended to be limiting.

The term “stiff” or “stiffness” as used herein refers to the extent to which an object resists deformation in response to an applied force. Under such an applied force, the object may undergo elastic deformation in correlation with such stiffness. For example, a stiff laminated panel may be one in which, after bending, the laminated panel returns to its original, as-laminated curvature, and a lighting element incorporated therein may also return to its original shape, for example, a flat state.

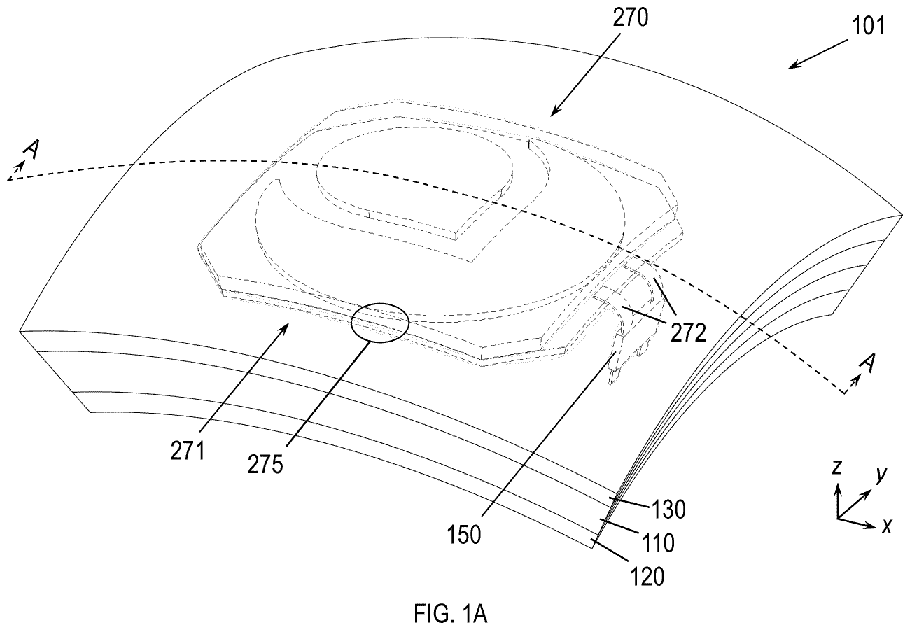

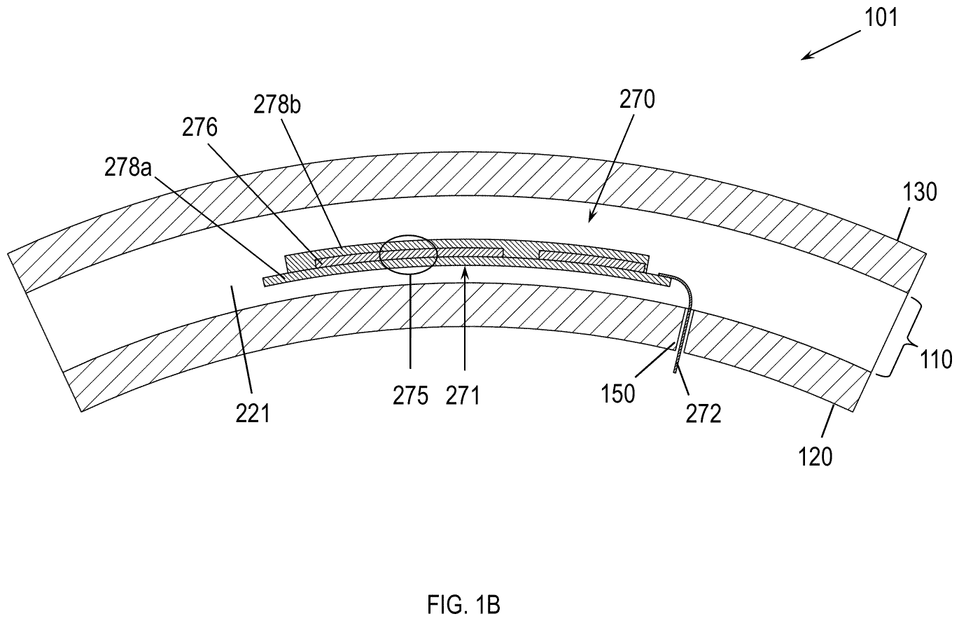

The drawings featured in the figures are provided for the purposes of illustrating some embodiments of the present disclosure. Accordingly, FIGS. 1A through 8C, for example, may contain sizes and shapes of respective portions that are appropriately exaggerated for ease of understanding, and the comparative sizes and/or shapes displayed in the drawings should be considered non-limiting.

In a first embodiment, shown in FIG. 1A and according to the present invention, a light emitting assembly LEA 270 may be integrated with a doubly-curved laminated panel 100 comprising a plurality of polymer layers, including a core 110 sandwiched by a substrate 120 and superstrate 130. The core 110 may further comprise a flowable polymer layer 112 which encapsulates the LEA 270. The laminated panel 100 may be curved about two axes, x and y. The radii of curvature about each axis, Rₚₓ and R_{py}, in one or more portions of the panel are generally such that the LEA 270 also bends in two directions. Alternatively, the LEA 270 may bend in one direction. Alternatively, the LEA 270 may remain flat. The local radii of curvature of any portion of the panel 100 may be equal or different in magnitude and/or sign. A pair of co-planar conductors 272, one for the transparent and one for the metallic electrode, exit the side of the panel 275. The conductors 272 may take the form of wires, a flexible printed circuit board (flex PCB), or laminated metal strips. The conductors 272 may be routed through a feedthrough 150 in the bottom of the laminated panel 100.

The LEA 270 may comprise any suitable light emitting device manufactured in a flexible planar form factor such as, for example, an electroluminescent (EL) lighting panel or pad 275, herein EL panel 275; the LEA 270 may comprise a light emitting diode (LED) panel or pad 280, herein LED panel 280. Such printed EL lighting panels 275 are available from TechnoMark, Inc., having a principle place of business at 11574 Encore Circle, Minnetonka, MN 55343, manufactured under the name PolyWeld™. Each light source may be energized by separate electrical connections made thereto, such as the electrodes of an EL capacitor or the electrodes of a plurality of LEDs.

A vehicle body panel comprising a solar array 200 may be configured with one or more LEAs 270, wherein the one or more LEAs 270 are positioned in any configuration and/or for any practical purpose. In this context, configurations and/or practical purpose may refer to exterior vehicle lighting positions, such as head light, rear light, etc. For example, two or more EL panels 275 may be employed on a single vehicle body panel, or across multiple vehicle body panels. Alternatively, an in a similar manner, two or more LED panels 280 may be employed on a single vehicle body panel, or across multiple vehicle body panels. Alternatively, one or more EL panels 275 may be employed with one or more LED panels on single vehicle panel, or across multiple vehicle panels. In one configuration, singular LEA 270 or an array of LEAs 270 may be purposed for each of right and left rear vehicle lights, respectively.

Referring to FIG. 1B, the light emitting element 271 may be an EL panel 275 comprising several layers, including a core 276 further comprising a phosphor-coated dielectric with transparent and metallic contacts (not shown) disposed on the top and bottom, respectively. An optional color filter (not shown) may be disposed on the phosphor-coated dielectric to select the color of the emitted light. The core 276 may be encapsulated by upper 278b and lower 278a insulating protective layers. A pair of co-planar conductors 272, may exit the side of the panel 275 and may be routed through a feedthrough 150 in the bottom of the laminated panel 100. The flowable polymer layer 112 may be selected to form a core 110 having sufficient thickness to absorb the non-planar topography and features of the LEA 270. The substrate 120 and superstrate 130 are purposed in part to provide further protection for the LEA 270.

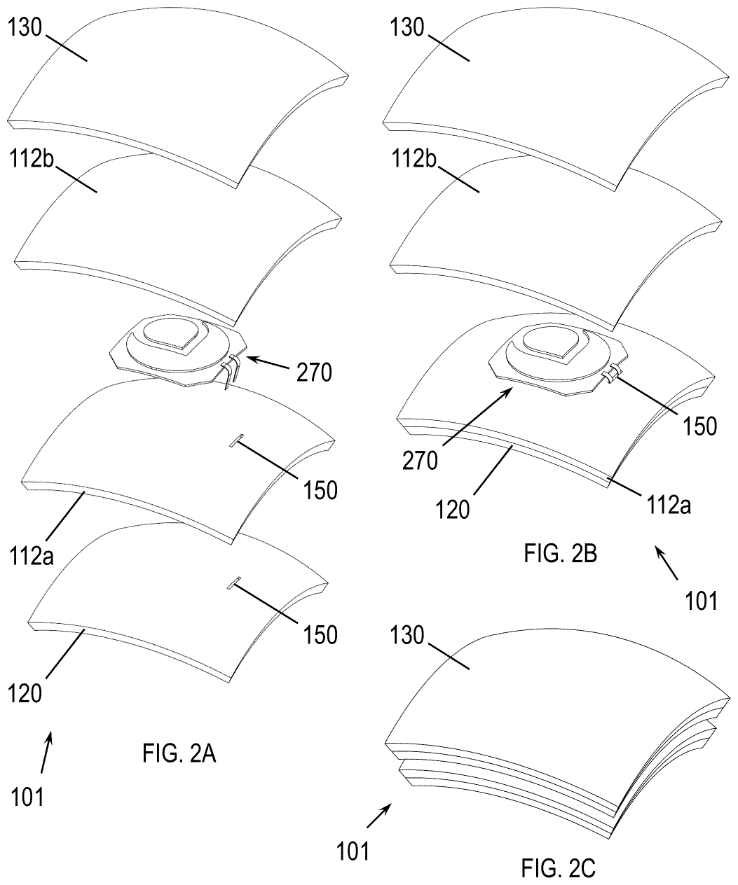

The present invention can use methods of manufacturing a solar panel 100 as described in certain applications commonly owned by Applicant, which are incorporated herein by reference in their entirety: U.S. patent application Ser. No. 18/169,576, entitled Curved Laminated Solar Panel And Method Of Manufacture Thereof, filed on Feb. 15, 2023; and PCT/US2023/064679, entitled Laminator Apparatus And Method Of Making Curved Laminated Solar Panel, filed on Mar. 18, 2023. Certain exemplary details of lamination processes for integrating the LEA 270 with a solar-enabled body panel are given in FIGS. 2A-2C. FIG. 2A illustrates the lamination stack, which may comprise a preformed substrate 120, a first encapsulant layer 112a, and light emitting assembly 270, a second encapsulant layer 112b, and a preformed superstrate 130. In a first step, the electrical termination feedthroughs 150 may be formed in the substrate and the first encapsulant layer 112a, as by, for example, mechanical or laser cutting. In a second step, as shown in FIG. 2B, the first encapsulant layer 112a may be aligned to, and disposed on, the preformed substrate 120. The encapsulant 112a may be aligned and/or undergo a wrinkle mitigation process. In a third step, also shown in FIG. 2B, the light emitting assembly 270 may be aligned to, and disposed on, the first encapsulant layer 112a and tacked into place by, for example, by heat applied in the form of hot air or conductive or radiative heating. Tacking of this form may advantageously eliminate unwanted movement of the LEA 270 during assembly of the lamination stack, the lamination process, or throughout other handling operations. The termination conductors 272 for the assembly 270 may be inserted into the feedthrough 150. In a fourth step, shown in FIG. 2C, a second encapsulant layer 112b and superstrate 130 may be aligned to, and disposed on, the substrate 120. Note that the latter two elements, the second encapsulant layer 112b and superstrate 130 may not uniformly contact the bottom layers 120 112a; but rather, they may rest principally on the light emitting assembly 270, thereby leaving a small gap. At this point, the stack may be inserted into a lamination machine for laminating.

In addition, or alternatively, FIGS. 2A-2C illustrate an LEA 270 employed in a panel 101 that, in the context, does not include a solar array 200, i.e., does not solar cells 210. Element 101 is designated so as to distinguish between solar panels 100 comprising a solar cell array 200. Panel 101, as described above, may comprise similar components as solar panel 100, but the configuration is characterized at least in part by LEA 270 and components thereof. Such a panel 101 may be employed, for example, on a vehicle pillar, i.e., the portion of the vehicle body extending upwardly in between the windshield and front, passenger-side window. This location is representative, and panel 101 may be configured on any body panel portion of a vehicle, in additional to other applications.

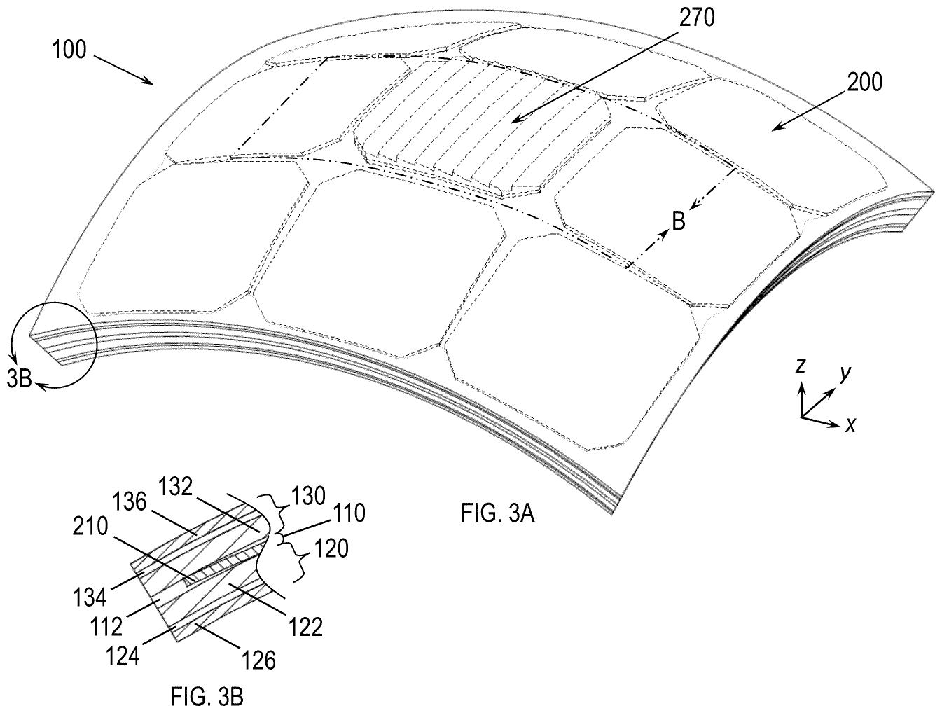

Referring to FIG. 3A, the present invention provides for integration of one or more LEAs 270 with a laminated solar panel 100 comprising a solar cell array 200 and embedded in a plurality of polymer layers. The solar panel 100 may be curved about two axes, x and y. The radii of curvature about each axis, Rₚₓ and R_{py}, in one or more portions of the panel are such that the cells 210 of the solar cell array 200 and the light emitting assembly 270 also bend in two directions. Alternatively, the LEA 270 may be curved in one direction, i.e., about one axis. Alternatively, the LEA 270 may remain flat. The local radii of curvature of any portion of the panel 100 may be equal or different in magnitude and/or sign. The LEA 270 can be formed with the light emitting element shaped similar to a solar cell 210, which typically has a 125×125 mm square shape with chamfered corners. The LEA 270 can be selected from light devices manufactured in a flexible planar form factor, such as, for example, an EL panel 275 or an LED panel 280 as previously described.

FIG. 3B illustrates the layers in the laminated solar panel which comprise a core 110 sandwiched by a substrate 120 and superstrate 130. The core 110 may comprise a flowable polymer layer 112 which encapsulates an array of solar cells 210 and the light emitting assembly 270. The substrate 120 may include one or more polymer layers that provide mechanical stiffness and a seal against water ingress. In this example, the substrate 120 may comprise a layer of polycarbonate (PC) 122, a layer of polyolefin elastomers (POE) 124, and a layer of ethylene tetrafluoroethylene (ETFE) 126. The ETFE 126 and POE layers 124 may provide a barrier to water ingress, reduce dirt accumulation (ETFE), and increase durability and reliability (POE). The superstrate 130 may include one or more polymer layers that provide mechanical stiffness, a seal against moisture, and resistance to damage caused by impact. In this embodiment, the superstrate 130 may comprise layer of PC 132, a layer of POE 134, and a layer of ETFE 136. The POE 124 may act as an adhesive layer between the PC 122 and POE 134, may provide mechanical stiffness, and/or may add to impact resistance. The ETFE 126 may act as a barrier to moisture, chemical vapor and oxygen transmission, and provides resistance to scratches and nicks. In an alternative embodiment, strengthened glass may be used for either the substrate or superstrate or both such as, for example, chemically strengthened or heat tempered glass.

The laminate layers may be chosen from a large variety of materials. For example, non-limiting alternatives for the PC layers include glass, polypropylene (PP), poly(methyl methacrylate) (PMMA), polyethylene terephthalate (PET), polyvinylchloride (PVC), polyethylene (PE), cyclic olefin copolymer (COC), and fluorinated ethylene propylene (FEP) to name a few. Non-limiting alternatives for the POE layers include polyvinyl butyral (PVB), thermoplastic olefin (TPO), ethylene-vinyl acetate (EVA), silicone, polyvinylidene difluoride (PVDF), thermoplastic polyurethane (TPU) to name a few. Non-limiting alternatives for the ETFE layers include glass and ethylene chlorotrifluoroethylene (ECTFE) among others.f

The laminate layers may be chosen to have a wide range of thicknesses. The thickness of the ETFE layer, for example, may be typically chosen within the range of 0.01-0.2 mm, with some applications using slightly thicker values. The thickness of the individual POE layers may be typically chosen within the range of 0.1-2 mm, for a total encapsulate thickness of between 0.2 and 4 mm. According to the present invention, when integrating a light element 270 that has a device thickness of about 0.5 to 1.5 mm, the POE layers may have a thickness of about 2.0 mm, for a total encapsulate thickness of about 4 mm. The thickness of the PC layer, for example, may be typically chosen within the range of 0.25-13 mm, with some applications using slightly thicker values. Also, the laminated stack may have different thicknesses for the layers both above and below the solar cells.

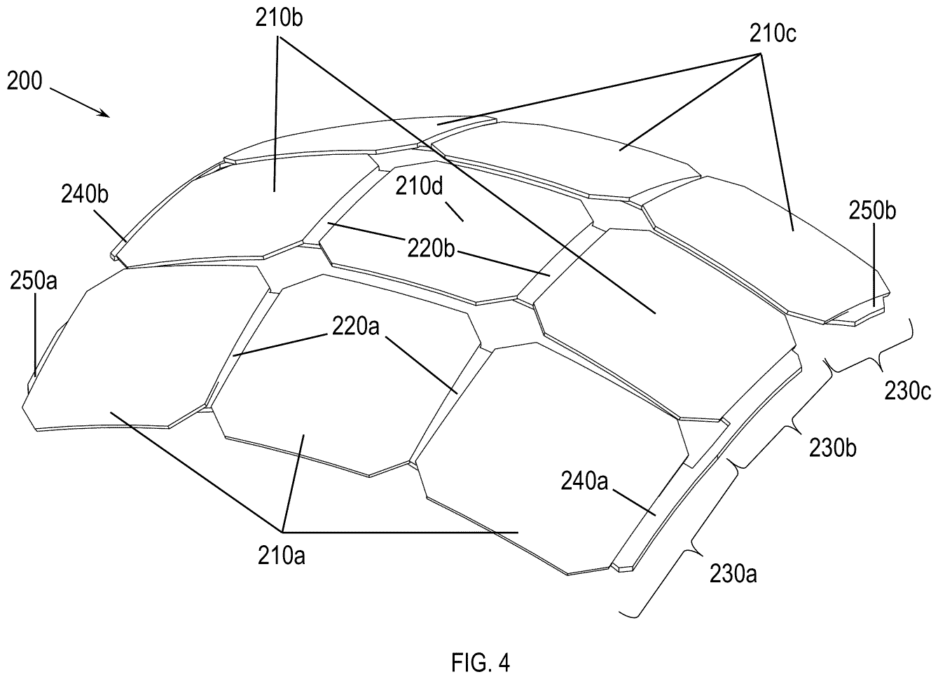

According to the present invention, a curved, laminated solar panel 100 can integrate an LEA 270 as illustrated and described in FIGS. 3A-8C. The core 110 of the solar panel 100 may include a solar cell array 200, as depicted in FIG. 4. The array 200 may be comprised of individual solar cells 210a-210d arranged in rows 230a-230c. In a first row 230a, individual cells 210a may be electrically connected by intra-row interconnects 220a, which may be soldered to the bottom side of the cells 210a-210d. Second 230b and third 230c rows may be similarly interconnected 220b, 220c. The rows 230a-230c may be electrically connected in a serpentine pattern by inter-row interconnects 240a, 240b. Alternatively, other series or parallel interconnect patterns may be used, depending on the application. At the end of the first 230a and last 230c rows a termination interconnect 250a, 250b may be disposed. According to an embodiment of the present invention, a LEA 270 may be substituted for an intra-row cell, such as cell 210d. The LEA 270 generally has an electrical connection that is separate from that of the solar cell array 200. Consequently, in such an arrangement, the intra-row interconnects 220b are replaced by a suitable, alternative interconnect.

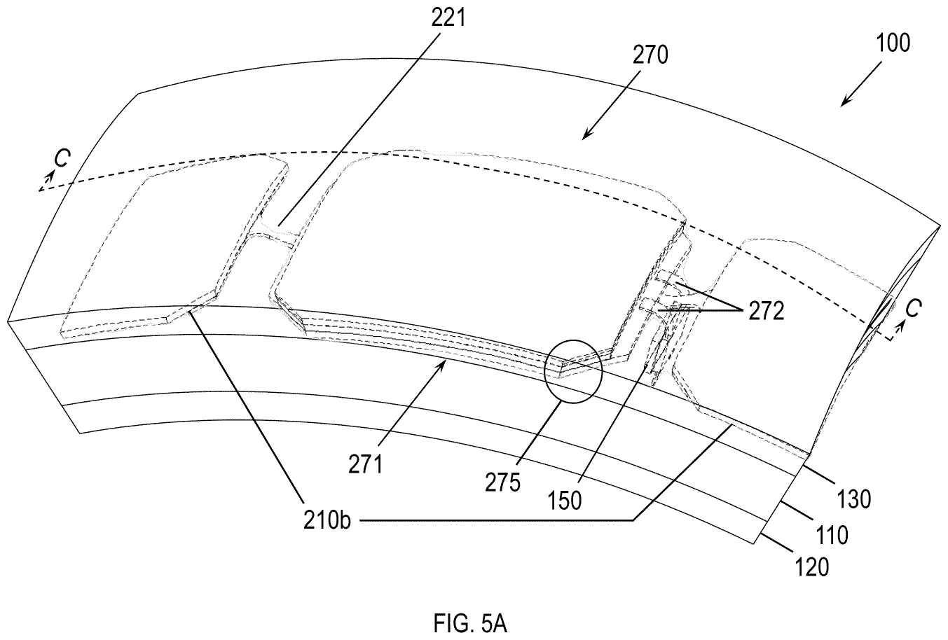

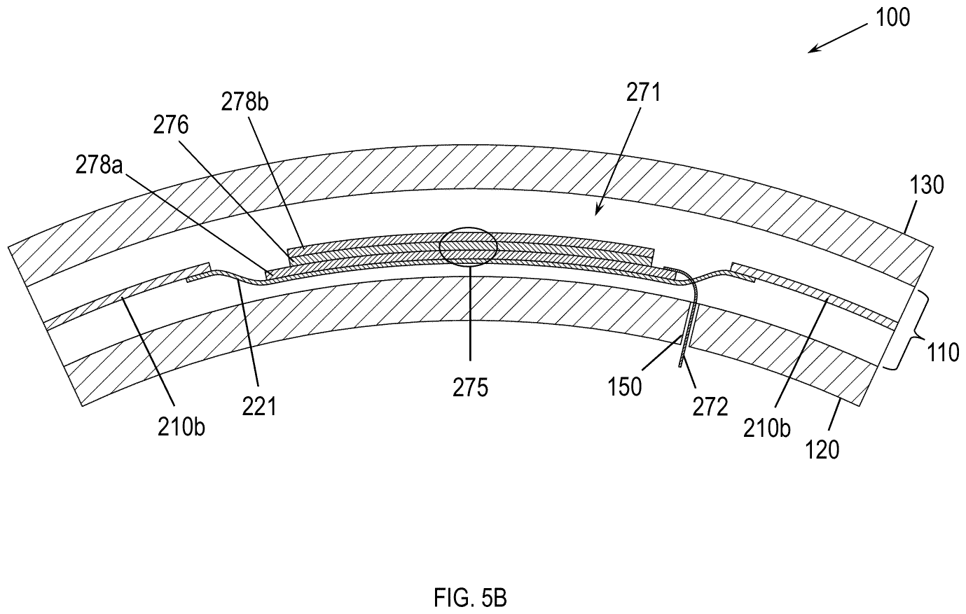

FIG. 5A illustrates an enlarged perspective view of a laminated solar cell array 200 wherein an LEA 270 has been substituted for an intra-row cell 210d, according to an embodiment of the present invention. In this embodiment, the light emitting element 271 comprises an EL panel 275. The EL panel 275 may terminate in a pair of conductors 272 that bend away from the plane of the panel and may be routed through a feedthrough 150 in the bottom of the panel so as to connect to a junction box and/or otherwise form an electrical circuit with the vehicle. In FIG. 5A, the LEA terminal conductors 272 are shown as straddling the solar cell interconnect 221. Alternatively, the terminal conductors 272 may be located to one or the other side of the solar cell interconnect 221.

Referring to FIG. 5B, the EL panel 275 may comprise several layers 275 including a core 276 having a phosphor-coated dielectric with transparent and metallic contacts (not shown) disposed on the top and bottom, respectively. An optional color filter (not shown) may be disposed on the phosphor-coated dielectric to select the color of the emitted light. The core 276 may be encapsulated by lower 278a and upper 278b insulating protective layers. A pair of co-planar conductors 272, one for the transparent electrode and one for the metallic electrode, may exit the side of the EL panel 275. The conductors 272 may take the form of wires, a flexible printed circuit board (flex PCB), laminated metal strips, or other electrical connection. The conductors 272 may be routed through a feedthrough 150 in the bottom of the solar panel 100. The intra-row solar cells 210b may be electrically coupled by a tunneling interconnect 221 such as, for example by a flexible circuit formed between polymer layers. The interconnect 221 may pass beneath the EL panel 275 and remain electrically isolated from the assembly conductors 272. In this way, the intra-row routing of the solar cells 210a-210d may remain unchanged and the EL panel 275, i.e., the LEA 270 more generally, may be placed anywhere with the solar cell array 200. The flowable polymer layer 112 may be chosen to form a core 110 having sufficient thickness to absorb the non-planar topography and features of the solar cell array 200 and LEA 270. The substrate 120 and superstrate 130 may provide further protection for these elements.

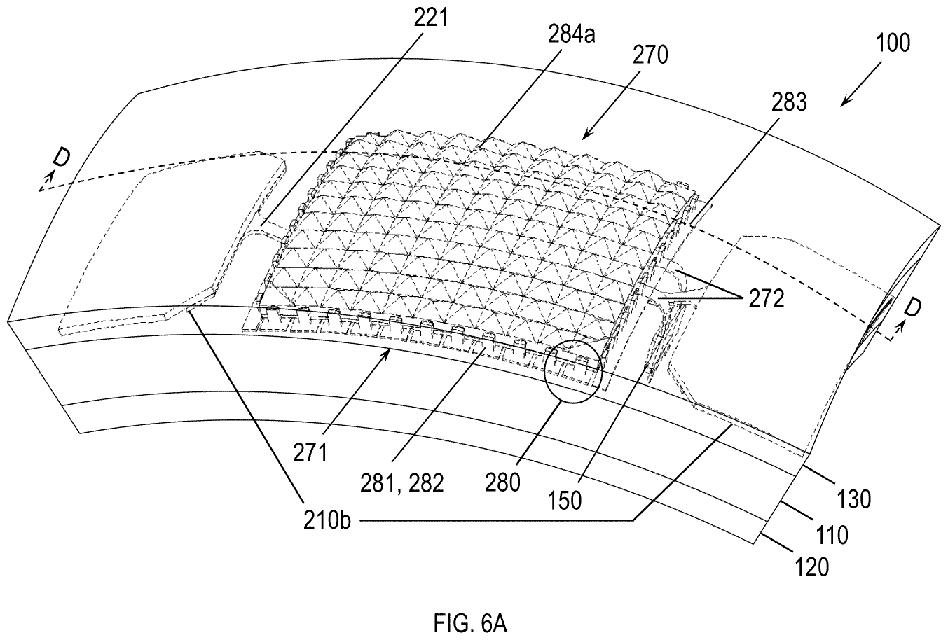

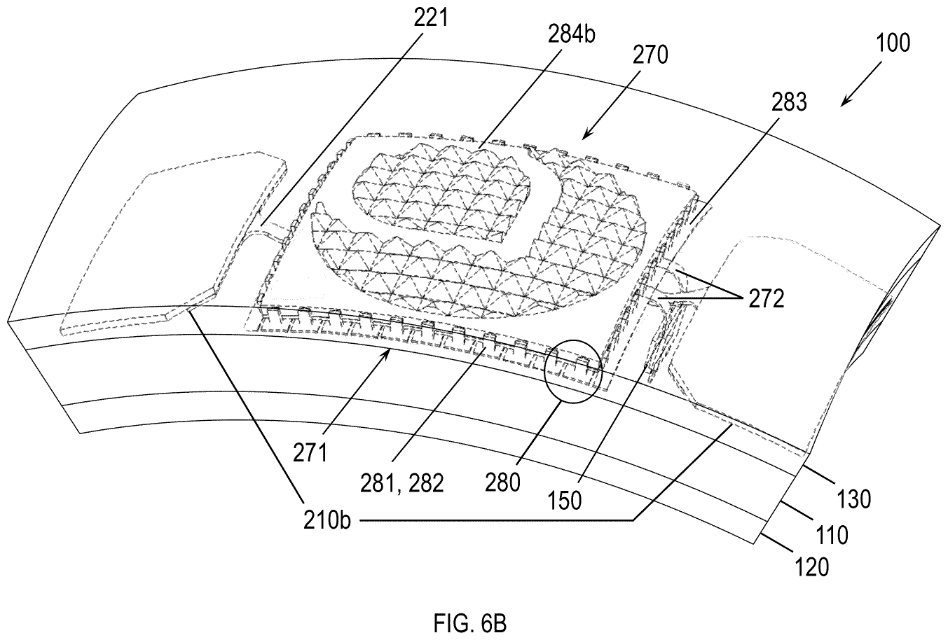

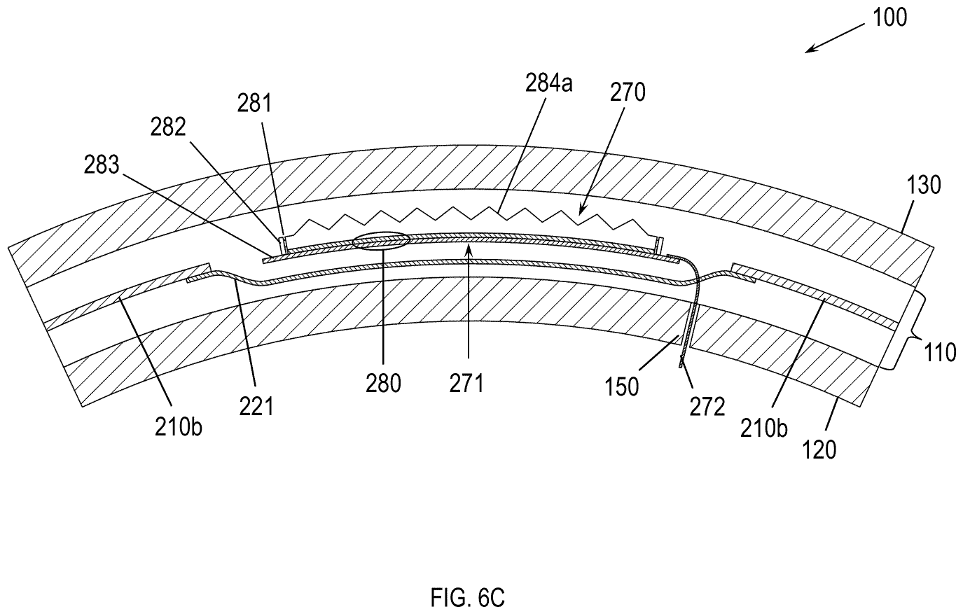

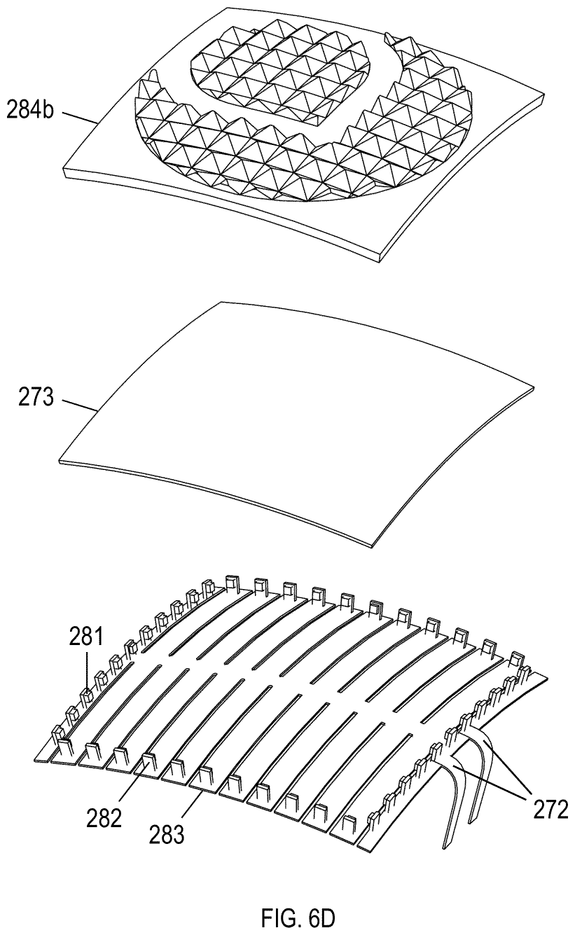

FIG. 6A illustrates an enlarged perspective view of a laminated solar cell array wherein an LEA 270 has been substituted for an intra-row cell 210d, according to an embodiment of the present invention. In this embodiment, the LEA 270 may comprise an LED panel 280 with an omnidirectional light guide/diffuser 284a. The LED panel 280 may comprise edge-firing LEDs optically coupled to the light guide 284a. The diffuser 284a may be made of any suitable material and has the properties of flexibility and a significant refractive index difference relative to the encapsulating core 110. The latter may be required for efficient refraction to occur. The surface of the light guide 284a, or portions thereof, may be shaped, patterned, or textured to enable light to escape the guide in a diffuse manner. The LED panel may be terminated in a pair of conductors 272 which bend away from the plane of the panel 100 and which may be routed through a feedthrough 150 in the bottom of the panel 100 so as to connect to a junction box 160 and/or otherwise form an electrical circuit with the vehicle. In FIG. 6A, the LEA 270 terminal conductors 272 may straddle the solar cell interconnect 221 substantially as shown. Alternatively, the terminal conductors 272 may be located to one or the other side of the solar cell interconnect 221.

Referring to FIG. 6B, an omnidirectional light guide/diffuser 284b may be shaped to emit light in a specific pattern, such as a logo. Other elements in FIG. 6B may take a similar form or the same form as that already described with respect to like-numbered elements in FIG. 6A.

FIG. 6C illustrates various details of the LED panel 280 of FIGS. 6A and 6B. LED panel 280 may comprise a flex PCB 283, including one or more sub-mounted 282 LEDs 281 surrounding a light guide/diffuser 284a. LEDs 281 may be formed in an array about diffuser 284a. According to embodiments thereof, a light guide film is used for location-selective diffusion. The light guide/diffuser 284a may redirect the light out of the plane of the solar panel 100 surface. An optional color filter (not shown) may be disposed on the LED panel 280 to more narrowly select the color of the emitted light. The LEDs 281 may be electrically connected in series or in parallel by traces on the sub-mounts 281 and flex PCB 283. A pair of co-planar conductors 272, one for the positive and one for the negative terminal, may exit the side of the panel 280. The conductors 272 may take the form of wires, a flexible printed circuit board (flex PCB), or laminated metal strips. The conductors may be routed through a feedthrough 150 in the bottom of the solar panel 100. The intra-row solar cells 210b may be electrically coupled by a tunneling interconnect 221. The interconnect 221 may pass beneath the light emitting assembly 270 and may remain electrically isolated from the LEA 270 conductors. In this way, the intra-row routing of the solar cells 210b may remain unchanged and the LED panel 280, or more generally LEA 270, may be placed anywhere within the solar cell array 200. The flowable polymer layer 112 may be chosen to form a core 110 having sufficient thickness to absorb the non-planar topography and features of the solar cell array 200 and light emitting assembly 270. The substrate 120 and superstrate 130 may provide further protection for these elements.

Certain aspects of the LED panel 280 are shown in the exploded view of FIG. 6D, where it may be more clearly seen, for example, how the panel 280 is constructed. At the bottom may be provided a flex PCB 283 which may be segmented in such a way that it is capable of bending in two directions. These relief cuts enable integration of the LED panel 280 with a doubly curved laminated panel 100, 101. Power may be supplied to the flex PCB 283 via termination electrodes 272 mounted at the edge. The flex PCB 283 may electrically couple an array of LEDs 281 mounted on sub-mounts 282. The sub-mounts 282 may be oriented such that the light from the LEDs 281 is principally directed toward, and efficiently coupled to, the light guide 284b. A reflector 273 may prevent light from escaping in a non-useful direction, such as through the bottom of the panel 280 according to the exemplary arrangement shown. The light guide 284b may incorporate a diffuser which partially covers the light guide 284b and that may allow light to emit in the shape of a logo.

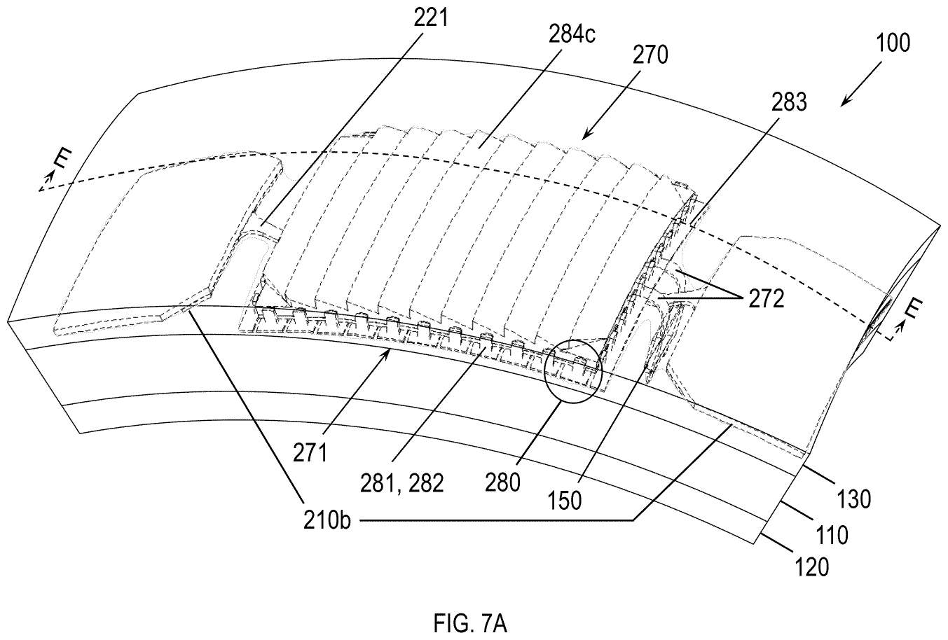

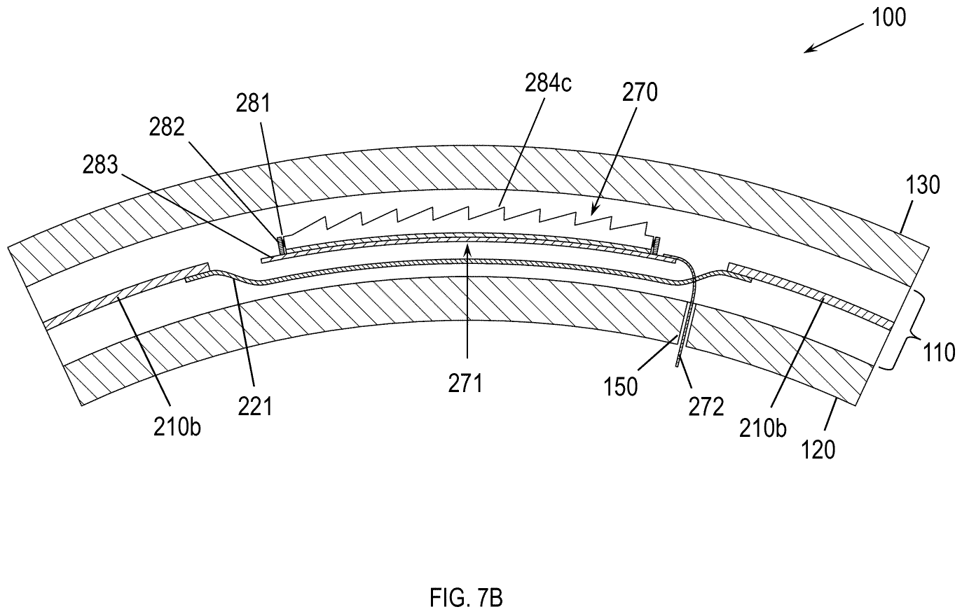

FIG. 7A illustrates a detail view of a laminated solar cell array wherein an LEA 270 has been substituted for an intra-row cell 210d, according to an embodiment of the present invention. In this embodiment, the LEA 270 comprises an LED panel 280 with a unidirectional light guide/diffuser 284c. The light guide/diffuser 284c may redirect the light at a shallow angle with respect to the solar panel 100 surface.

Referring to FIG. 7B, the LED panel 280 may comprise several layers including a flex PCB 283 and an array of sub-mounted 282 LEDs 281 surrounding the light guide/diffuser 284c. The diffuser 284c may be made of any suitable material and has the properties of flexibility and a significant refractive index difference relative to the encapsulating core 110. The latter may be required for efficient refraction to occur.

According to an embodiment of the present invention as exemplified in FIG. 3A, the laminated solar panel 100 can be configured as a tailgate having the LEA 270 and a plurality of photovoltaic cells 210 arranged a desired pattern of a solar cell array 200. However, the laminated solar panel 100 having the LEA 270 and a plurality of photovoltaic cells 210 is not limited to a particular vehicle panel. Other possible panels include, but are not limited to, a door, pillar, hood, or other useful location where a light element combined in a panel is contemplated for operational use of light illumination such as an accent light, a decorative light, a keypad, and a backlit logo.

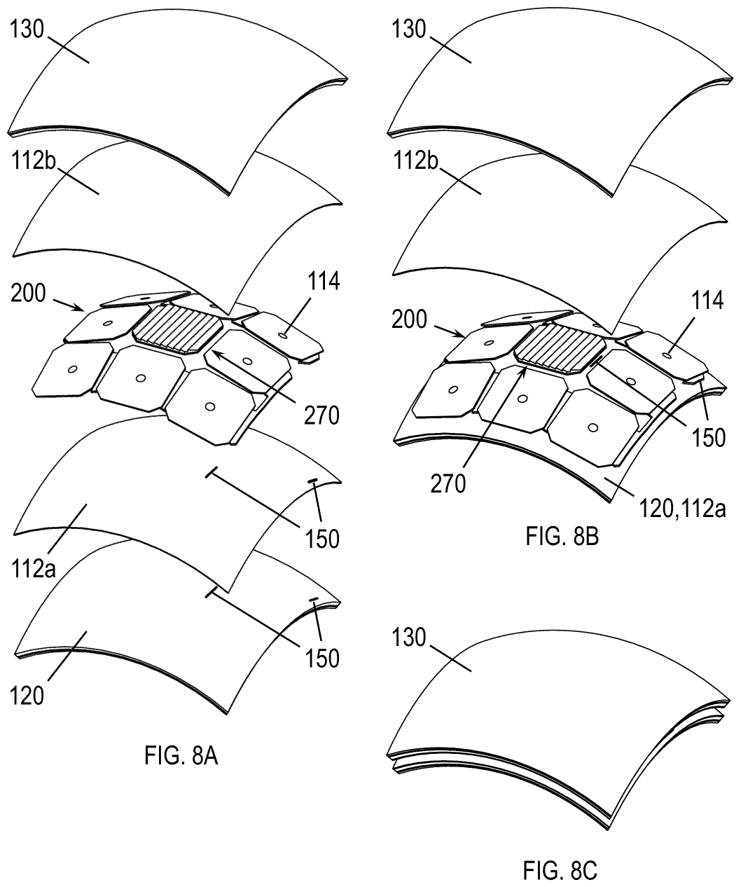

The present invention can use methods of manufacturing laminated solar panels 100, as previously disclosed. Some details of the lamination process for integrating the LEA 270 with a solar-enabled body panel are illustrated in FIGS. 8A-8C. FIG. 8A displays the lamination stack, which may comprise a preformed substrate 120, a first encapsulant layer 112a, a solar cell array 200 and light emitting assembly 270, a second encapsulant layer 112b, and a preformed superstrate 130. In a first step, the electrical termination feedthroughs 150 may be formed in the substrate and the first encapsulant layer 112a, as by, for example, mechanical or laser cutting. In a second step, shown in FIG. 8B, the first encapsulant layer 112a may be aligned to, and disposed on, the preformed substrate 120. The encapsulant 112a may be aligned and/or wrinkle mitigated. In a third step, the solar cell array and interconnects 200 may be aligned to, and disposed on, the first encapsulant layer 112a and tacked into place by, for example, heat applied in the form of hot air or conductive or radiative heating at the tack points 114 on each cell. The tacks 114 may advantageously eliminate unwanted movement of the solar cells 210 during assembly, lamination or other heating operations. The termination conductors for the array 200 may be inserted into the array feedthrough 150. In a fourth step, the light emitting assembly 270 may be aligned and placed in its position in the array 200 and tacked into place 114. The termination conductors for the assembly 270 may be inserted into the assembly feedthrough 150. Alternatively, steps 3 and 4 may be combined such that the light emitting 270 and light receiving 200 elements may be aligned and tacked simultaneously. In a fifth step, shown in FIG. 8C, a second encapsulant layer 112b and superstrate 130 may be aligned to and disposed on the substrate 120. Note that the latter two elements 112b 130 may not uniformly contact the bottom layers 120 112a, but rather may rest principally on the solar cell array 200 and LEA 270, thereby leaving a small gap. The stack is then ready for insertion into a lamination machine for laminating.

While certain configurations of structures have been illustrated for the purposes of presenting the basic structures of the present invention, one of ordinary skill in the art will appreciate that other variations are possible which would still fall within the scope of the appended claims. Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A light emitting panel comprising:
a substrate and a superstrate each including one or more preformed, doubly-curved layers, said substrate and superstrate being preformed in a complementary shape when said panel is in an assembled configuration; and
a core disposed therebetween, said core comprising at least one light emitting diode and/or at least one electroluminescent element encapsulated by one or more encapsulant layers;
wherein in said assembled configuration, said core is integrally formed with said substrate and said superstrate.

2. The light emitting panel according to claim 1, wherein said one or more preformed layers of said substrate and said superstrate comprise preformed and thermally or chemically strengthened glass.

3. The light emitting panel according to claim 1, wherein said one or more preformed layers of said substrate and said superstrate comprise layers that have been laminated and thermoformed.

4. A light emitting solar panel comprising:
a substrate and a superstrate each including one or more preformed layers, said substrate and superstrate being preformed in a complementary shape when said solar panel is in an assembled configuration; and
a core disposed therebetween, said core comprising at least one light emitting diode and/or electroluminescent element and a solar cell array including at least one solar cell, said at least one light emitting diode and/or at least one electroluminescent element and solar cell array being encapsulated by one or more encapsulant layers;
wherein in said assembled configuration, said core is integrally formed with said substrate and said superstrate such that said at least one solar cell of said solar cell array is curved along two orthogonal axes;
and wherein said at least one light emitting diode and/or electroluminescent element and said solar cell array are electrically decoupled.

5. The light emitting solar panel according to claim 4, wherein said one or more preformed layers of said substrate and said superstrate comprise preformed and thermally or chemically strengthened glass.

6. The light emitting solar panel according to claim 4, wherein said one or more preformed layers of said substrate and said superstrate comprise layers that have been laminated and thermoformed.

7. The light emitting solar panel according to claim 4, wherein the electrical interconnects for said solar cell array pass beneath said at least one light emitting diode and/or electroluminescent element.

8. The light emitting solar panel according to 4, wherein either or both of said substrate and said superstrate comprise at least one rigid layer.

9. The light emitting solar panel according to claim 6, wherein either or both of said substrate and said superstrate comprise at least one rigid layer and at least one adhesive layer.

10. The light emitting solar panel according to claim 9, wherein either or both of said substrate and said superstrate comprise an outer protective layer, an inner rigid layer and one adhesive layer disposed therebetween.

11. The light emitting solar panel according to claim 10, wherein said inner rigid layer is a material selected from the group consisting of: polycarbonate (PC), glass, polypropylene (PP), polymethyl methacrylate (PMMA), polyethylene terephthalate (PET), polyvinylchloride (PVC), polyethylene (PE), cyclic olefin copolymer (COC), and fluorinated ethylene propylene (FEP).

12. The light emitting solar panel according to claim 10, wherein said outer protective layer is a material selected from the group consisting of: ethylene tetrafluoroethylene (ETFE), glass, and ethylene chlorotrifluoroethylene (ECTFE).

13. The light emitting solar panel according to claim 9, wherein said adhesive layer is a material selected from the group consisting of: acrylic-based or silicone-based adhesive transfer tape.

14. The light emitting solar panel according to claim 11, wherein said inner rigid layer is a material having an elastic modulus ranging from about 1.79 GPa to about 3.24 GPa.

15. The light emitting solar panel according to claim 12, wherein said outer protective layer is a material having an elastic modulus ranging from about from about 0.490 GPa to about 0.827 GPa.

16. A method of manufacturing a light emitting solar panel comprising the steps of:
preforming a substrate and a superstrate;
disposing a core between said substrate and said superstrate to form a lamination stack, said core comprising at least one light emitting element and a solar cell array including at least one solar cell arranged proximate at least one encapsulant layer;
laminating said lamination stack to form a solar panel, so that said encapsulant encapsulates said solar cell array and said light emitting element, said lamination bending said at least one solar cell along two orthogonal axes.

17. The method of manufacturing a light emitting solar panel according to claim 16 wherein said preforming step includes the steps of:
laminating said substrate and said superstrate in a flat state; and
thermoforming said substrate and said superstrate into an offset double-curved shape.

18. The method of manufacturing a light emitting solar panel according to claim 16 wherein said core disposition includes the step of tacking said at least one solar cell to at least one encapsulant layer.

19. The method of manufacturing a light emitting solar panel according to claim 16, wherein said lamination process applies substantially uniform pressure across the at least one solar cell of the solar cell array curved along two orthogonal axes.

20. The method of manufacturing a light emitting solar panel according to claim 19, wherein said substantially uniform pressure comprises applying pressure so that said substrate initially moves said at least one cell at a downward-facing side center, and said superstrate simultaneously moves said at least one cell at upward-facing side corners, thereby bending said at least one cell by applying said substantially uniform pressure.
